(19) United States
(12) Patent Application Publication
(10) Pub. No.: US 2014/0174629 A1
(43) Pub. Date: Jun. 26, 2014

(54) METHOD FOR MANUFACTURING LIGHT EMITTING DIODE MODULE

(71) Applicant: HON HAI PRECISION INDUSTRY CO., LTD., New Taipei (TW)

(72) Inventor: CHIH-CHEN LAI, New Taipei (TW)

(21) Appl. No.: 13/931,773

(22) Filed: Jun. 28, 2013

(30) Foreign Application Priority Data
Dec. 24, 2012 (TW) 101149451

(51) Int. Cl. H05K 3/30; F21K 99/00

(52) U.S. Cl. CPC H05K 3/305; F21K 9/90
USPC 156/64

(57) ABSTRACT

A method for manufacturing an LED module includes following steps: providing a SMT apparatus having a CCD image sensor and a nozzle, and providing a PCB having a plurality of LEDs mounted on and fixing the PCB in the SMT apparatus; providing a plurality of lenses each having a plurality of patterned portions formed on an outer face of the lens; providing an adhesive area in the SMT apparatus, disposing a plurality of adhesive on the adhesive area, and the nozzle carrying each lens to the adhesive area; carrying each lens by the nozzle upwardly from the adhesive area, and the CCD image sensor imaging the lens and identifying the patterned portions, and then the SMT apparatus obtaining a location of the lens relative to a corresponding LED; and positioning and fixing the lens on the PCB to cover the LEDs by the SMT apparatus.

### BACKGROUND

1. Technical Field

The disclosure generally relates to a method for manufacturing a light emitting diode (LED) module.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

A conventional backlight module includes a flat back cover and a plurality of LED modules mounted on the back cover in array. Each of the LED modules should have an illumination angle as large as possible. To achieve this objective, an optical lens is usually required to be placed above the LED. Generally, in a conventional method for manufacturing the LED module, the LEDs are firstly fixed on a PCB by SMT (Surface Mount Technology) apparatus, and then the lenses are correspondingly positioned above the LEDs, finally the lenses are fixed on the PCB.

However, it is hard to position the lenses corresponding to the LEDs accurately, it may cause unsuitable light emitting effect of the LED module.

What is needed, therefore, is a method for manufacturing an LED module to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a flow chart of a method for manufacturing an LED module in accordance with an embodiment of the present disclosure.

FIG. 2 shows step S101 of the method of FIG. 1.

FIG. 3 shows step S103 of the method of FIG. 1.

FIG. 4 shows step S104 of the method of FIG. 1.

FIG. 5 shows step S105 of the method of FIG. 1.

FIG. 6 is a schematic, bottom view of a lens of the LED module manufactured by the method of FIG. 1.

### DETAILED DESCRIPTION

Embodiments of a method for manufacturing a light emitting diode (LED) module will now be described in detail below and with reference to the drawings.

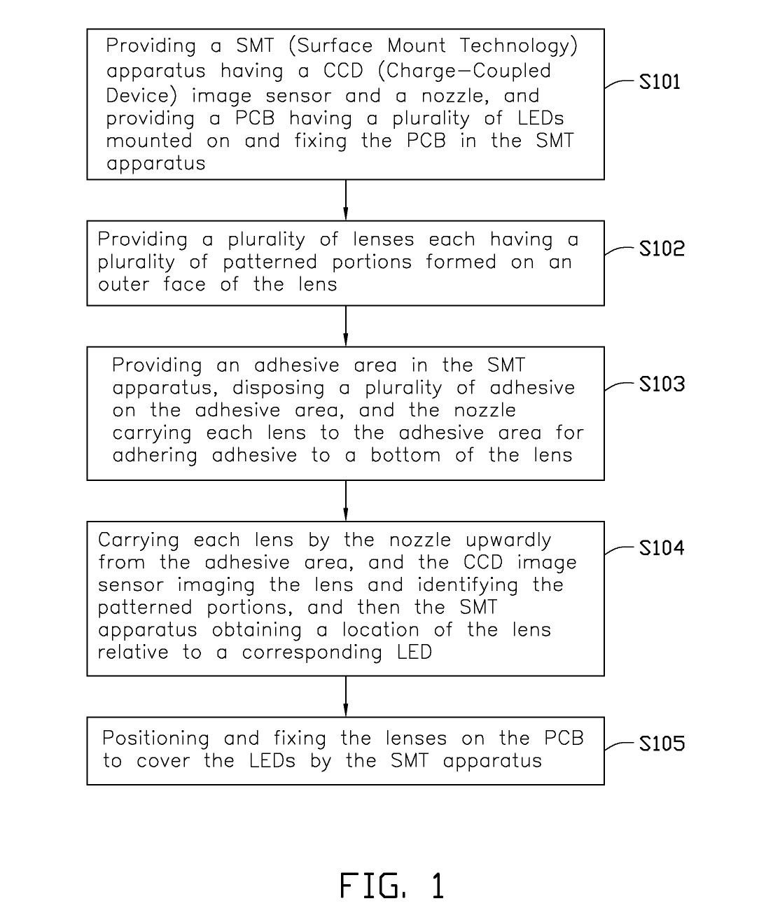

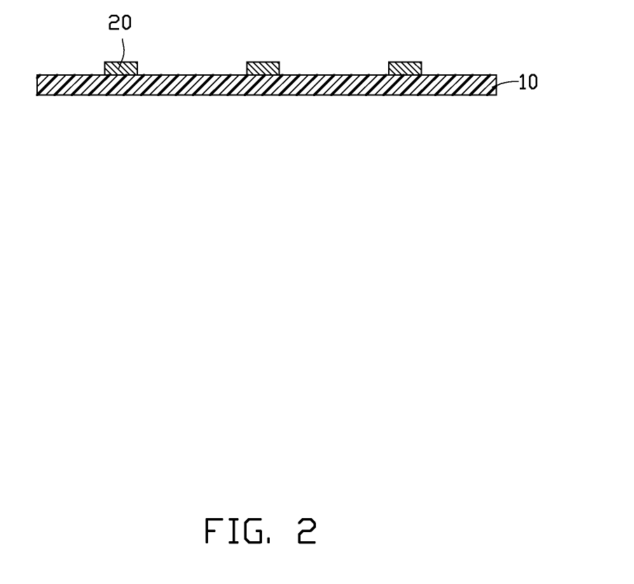

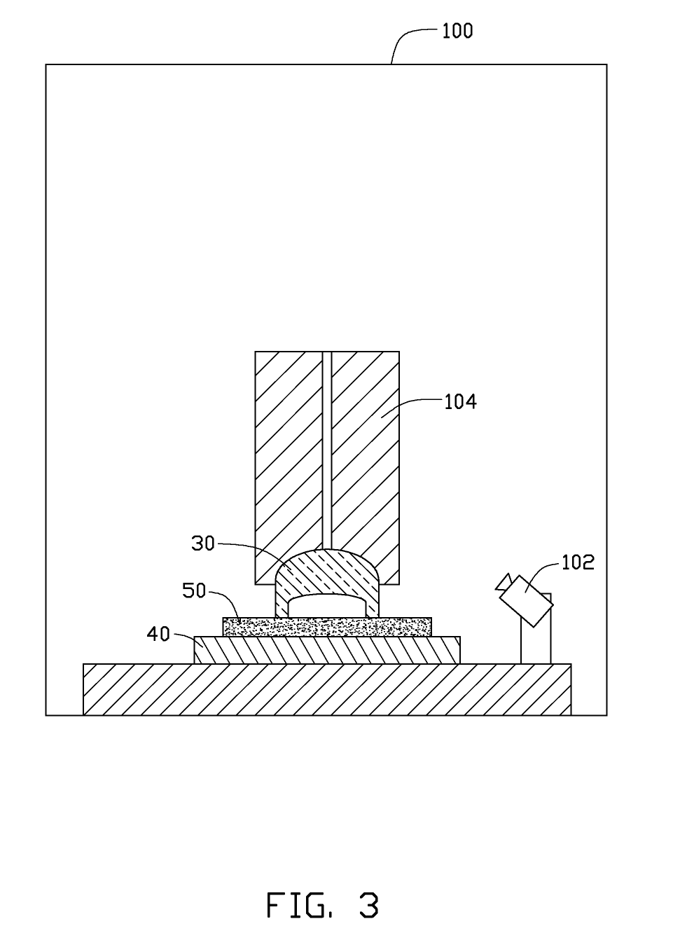

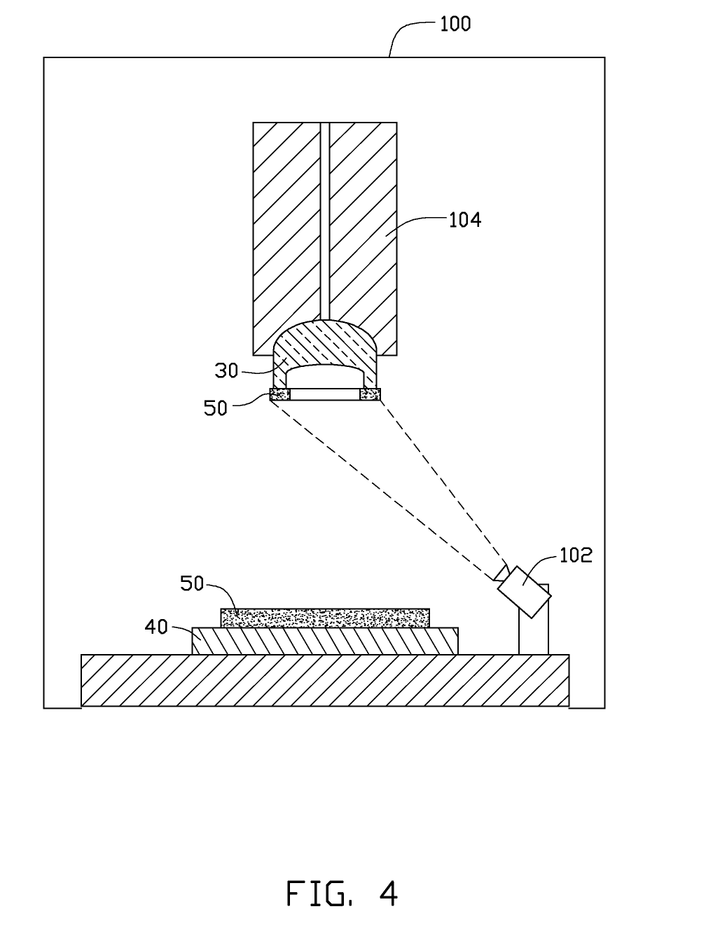

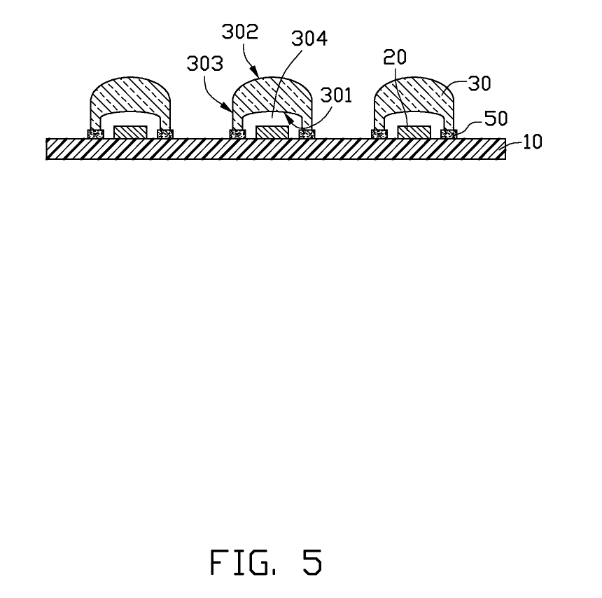

Referring to FIGS. 1-5, a method for manufacturing an LED module in accordance with an exemplary embodiment is provided.

Step S101, a SMT (Surface Mount Technology) apparatus 100 is provided, and an elongated PCB 10 having a plurality of LEDs 20 mounted on is positioned in the SMT apparatus 100. The SMT apparatus 100 has a CCD (Charge-Coupled Device) image sensor 102 and a nozzle 104.

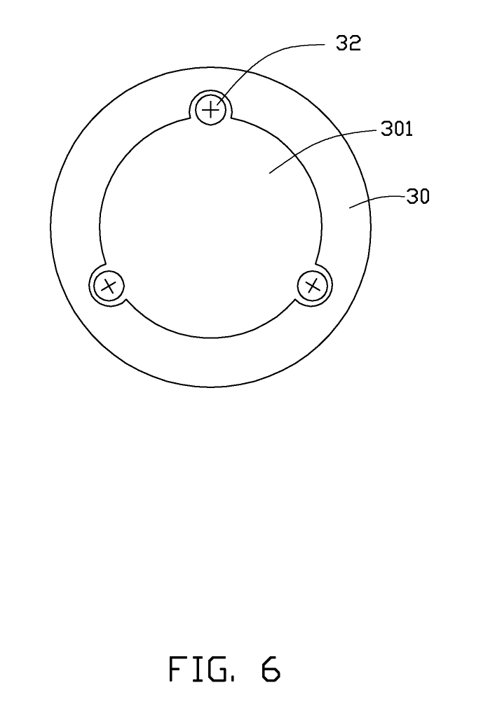

Step S102, a plurality of lenses 30 are provided. As FIG. 6 shown, each lens 30 has a plurality of patterned portions 32 formed on an outer face of the lens 30.

Step S103, an adhesive area 40 is provided in the SMT apparatus 100, a plurality of adhesive 50 are located on the adhesive area 40, and each lens 30 is carried by the nozzle 104 to the adhesive area 40 for adhering the adhesive 50 to a bottom of the lens 30.

Step S104, each lens 30 is carried by the nozzle 104 upwardly from the adhesive area 40, the lens 30 is imaged by the CCD image sensor 102, the patterned portions 32 are identified by the CCD image sensor 102, a location of the lens 30 relative to a corresponding LED 20 is obtained by the SMT apparatus 100.

Step S105, the lenses 30 are correspondingly fixed on the PCB 10 and cover the LEDs 20 by the SMT apparatus 100.

In detail, a manner of positioning each lens 30 on the PCB 10 by the SMT apparatus 100 includes following steps. Firstly, the PCB 10 with the LEDs 20 mounted thereon is fixed in the SMT apparatus 100. Secondly, a corresponding lens 30 is carried by the nozzle 104 of the SMT apparatus 100. Thirdly, the lens 30 is imaged by the CCD image sensor 102, and the patterned portions 32 of the lens 30 are identified by the CCD image sensor 102. Fourthly, a location variation between the lens 30 and a corresponding LED 20 on the PCB 10 is calculated by the SMT apparatus 100. Finally, the lens 30 is positioned on the PCB 10 and covers the corresponding LED 20 by the nozzle 104 of the SMT apparatus 100, according to the location variation.

Each lens 30 is integrally made of transparent materials such as PC (polycarbonate) or PMMA (polymethyl methacrylate). A dimension of the lens 30 is about 3 mm.

Each lens 30 includes a light-incident face 301 facing the LED 20, a light-emitting face 302 opposite to the light-incident face 301, and a connecting face 303 interconnecting the light-incident face 301 and the light-emitting face 302. A center of a bottom portion of the lens 30 is recessed inwardly to form a dome-like receiving room 304 for accommodating the LED 20 therein.

Referring to FIG. 6 again, each lens 30 further includes at least one patterned portion 32 configured for being observed in imaging and locating by the SMT apparatus 100. It can be understood that, the patterned portion 32 could be formed on the light-incident face 301, the light-emitting face 302 or the connecting face 303 of the lens 30. In this embodiment of the disclosure, the patterned portion 32 is formed on the light-incident face 301 of the lens 30. A dimension of the patterned portion 32 is about 0.1 mm. In this embodiment of the disclosure, there are three patterned portions 32 evenly spaced from each other.

Additionally, in step S104, when the lens 30 is imaged by the CCD image sensor 102, the CCD image sensor 102 also checks the adhesive 50 adhering to the bottom of the lens 30. If the adhesive 50 is not sufficient, a grayscale brightness of an area of the adhesive 50 is higher than a predetermined value, and in this situation, the lens 30 would be carried by the nozzle 104 to the adhesive area 40 for adhering the adhesive 50 to the bottom of the lens 30 again.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing a light emitting diode (LED) module, comprising following steps:
providing a SMT (Surface Mount Technology) apparatus having a CCD (Charge-Coupled Device) image sensor and a nozzle, and providing a PCB having a plurality of LEDs mounted on and fixing the PCB in the SMT apparatus;
providing a plurality of lenses each having a plurality of patterned portions formed on an outer face of the lens;
providing an adhesive area in the SMT apparatus, disposing a plurality of adhesive on the adhesive area, and the nozzle carrying each lens to the adhesive area for adhering adhesive to a bottom of the lens;
carrying each lens by the nozzle upwardly from the adhesive area, and the CCD image sensor imaging the lens and identifying the patterned portions, and then the SMT apparatus obtaining a location of the lens relative to a corresponding LED; and
positioning and fixing the lenses on the PCB to cover the LEDs by the SMT apparatus.

2. The method of claim 1, wherein a manner of positioning a corresponding lens on the PCB by the SMT apparatus comprises following steps: fixing the PCB with the LEDs mounted thereon in the SMT apparatus; carrying the corresponding lens by the nozzle of the SMT apparatus; the CCD image sensor imaging the lens and identifying the patterned portions to locate the lens relative to a corresponding LED on the PCB; the SMT apparatus calculating a location variation between the lens and the corresponding LED; and the nozzle of the SMT apparatus positioning the lens on the PCB to cover the corresponding LED, according to the location variation.

3. The method of claim 1, wherein a dimension of each lens is 3 mm.

4. The method of claim 1, wherein each lens comprises a light-incident face facing the LED, a light-emitting face opposite to the light-incident face, and a lateral face interconnecting the light-incident face and the light-emitting face.

5. The method of claim 4, wherein the patterned portions are formed on the light-incident face.

6. The method of claim 4, wherein the patterned portions are formed on the light-emitting face.

7. The method of claim 4, wherein the patterned portions are formed on the lateral face.

8. The method of claim 1, wherein when the lens is imaged the CCD image sensor, the CCD image sensor also checks the adhesive adhering to the bottom of the lens, if the adhesive is not sufficient, a grayscale brightness of an area of the adhesive is higher than a predetermined value, and in this situation, the lens is carried by the nozzle to the adhesive area for adhering adhesive to the bottom of the lens again.

9. The method of claim 1, wherein the patterned portions are evenly spaced from each other.

10. The method of claim 1, wherein a dimension of each patterned portion is 0.1 mm.

11. A method for manufacturing a light emitting diode (LED) module, comprising following steps:
providing a SMT apparatus having a CCD image sensor and a nozzle, and providing a PCB having an LED mounted on and fixing the PCB in the SMT apparatus;
providing a lens having a plurality of patterned portions formed on an outer face of the lens;
providing an adhesive area, disposing a plurality of adhesive on the adhesive area, and the nozzle carrying the lens to the adhesive area for adhering adhesive to a bottom of the lens;
carrying the lens by the nozzle upwardly from the adhesive area, and the CCD image sensor imaging the lens and identifying the patterned portions, and then the SMT apparatus obtaining a location of the lens relative to the LED; and
positioning and fixing the lens on the PCB to cover the LED by the SMT apparatus.

12. The method of claim 11, wherein a manner of positioning the lens on the PCB by the SMT apparatus comprises following steps: fixing the PCB with the LED mounted thereon in the SMT apparatus; carrying the corresponding lens by the nozzle of the SMT apparatus; the CCD image sensor imaging the lens and identifying the patterned portions to locate the lens relative to the LED on the PCB; the SMT apparatus calculating a location variation between the lens and the LED; and the nozzle of the SMT apparatus positioning the lens on the PCB to cover the LED, according to the location variation.

13. The method of claim 11, wherein a dimension of the lens is 3 mm.

14. The method of claim 11, wherein the lens comprises a light-incident face facing the LED, a light-emitting face opposite to the light-incident face, and a lateral face interconnecting the light-incident face and the light-emitting face.

15. The method of claim 14, wherein the patterned portions are formed on the light-incident face.

16. The method of claim 14, wherein the patterned portions are formed on the light-emitting face.

17. The method of claim 14, wherein the patterned portions are formed on the lateral face.

18. The method of claim 11, wherein when the lens is imaged the CCD image sensor, the CCD image sensor also checks the adhesive adhering to the bottom of the lens, if the adhesive is not sufficient, a grayscale brightness of an area of the adhesive is higher than a predetermined value, and in this situation, the lens is carried by the nozzle to the adhesive area for adhering adhesive to the bottom of the lens again.

19. The method of claim 11, wherein the patterned portions are evenly spaced from each other.

20. The method of claim 11, wherein a dimension of each patterned portion is 0.1 mm.
